(19) United States
(12) Patent Application Publication
(10) Pub. No.: US 2007/0196984 A1
(43) Pub. Date: Aug. 23, 2007

(54) Nonvolatile memory device, layer deposition apparatus and method of fabricating a nonvolatile memory device using the same

(75) Inventors: Jung-hyun Lee, Yongin-si (KR); Sang-bong Bang, Yongin-si (KR); Sang-jun Choi, Yongin-si (KR); Bum-seok Seo, Yongin-si (KR); Chang-soo Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/655,191

(22) Filed: Jan. 19, 2007

(30) Foreign Application Priority Data
Feb. 22, 2006 (KR) 10-2006-0017243

(51) Int. Cl. H01L 21/336

(52) U.S. Cl. 438/257

(57) ABSTRACT

Provided are a nonvolatile memory device, a layer deposition apparatus and a method of fabricating a nonvolatile memory device using the same. The apparatus may include a chamber capable of holding a substrate, a particle-discharging target discharging particles toward the substrate, and a first ion beam gun accelerating a first plurality of ions and irradiating the accelerated ions toward the substrate. The method of fabricating a nonvolatile memory device may include discharging particles from a target toward a substrate, accelerating and irradiating a first plurality of ions toward the substrate, forming a reaction product by reacting the discharged particles and the accelerated and irradiated first plurality of ions, and forming a data storage layer having a deposited layer on the substrate. The nonvolatile memory device may include a data storage layer including a transition metal oxide layer formed by reacting discharged transition metal particles and accelerated and irradiated oxygen ions.

### PRIORITY STATEMENT

This application claims the benefit of priority under 35 U.S.C. §119 from Korean Patent Application No. 10-2006-0017243, filed on Feb. 22, 2006 in the Korean Intellectual Property Office, the disclosure of which is incorporated herein in its entirety by reference.

### BACKGROUND

1. Field

Example embodiments relate to a nonvolatile memory device, a layer deposition apparatus and a method of fabricating a nonvolatile memory device using the same.

2. Description of the Related Art

High speed nonvolatile memory devices including a ferroelectric random access memory (FRAM), a magnetic random access memory (MRAM), a phase change random access memory (PRAM) and a resistive random access memory (RRAM) have been the focus of recent studies.

RRAM stores binary information using a resistance switching characteristic formed of a transition metal oxide material. Resistance of the transition metal oxide material may change according to a voltage or current supplied to a transition metal oxide material. The transition metal oxide material may be laminated in the form of a thin film on a substrate in order to use a lower voltage, achieve higher integration and/or higher operation speed characteristics in semiconductor memory devices. Conventionally, a sputtering method may be used to form the thin transition metal oxide layer on the substrate. The sputtering method may be a type of physical vapor deposition (PVD).

FIG. 1 is diagram illustrating a cross-sectional view of a conventional layer deposition apparatus.

Referring to FIG. 1, the conventional layer deposition apparatus 10 (hereinafter ‘conventional apparatus’) may include a chamber 11, a substrate 12, a target 15, an oxygen supplying unit 18 and an argon supplying unit 19. An inner area of the chamber 11 may be in a vacuum state. The substrate 12 may be formed (or positioned) inside the chamber 11. The target 15 may be inside the chamber 11 and above the substrate 12. The oxygen (O₂) supplying unit 18 may supply oxygen (O₂) gas to an area around the substrate 12. The argon (Ar) supplying unit 19 may supply Ar gas to an area around the target 15.

If radio frequency (RF) power is supplied to the target 15, then the Ar gas supplied around the target 15 through the argon supplying unit 19 may become a plasma that generates Ar ions. The Ar ions may collide with the surface of the target 15. As a result of the collision of the Ar ions with the surface of the target 15, transition metal particles may be discharged from the target 15 and fall down on (or contact) the substrate 12. If the substrate 12 is supplied with heat energy and the O₂ gas is supplied around the substrate 12, then the discharged transition metal particles and the O₂ gas may react with each other, forming a reaction product on the substrate 12. The reaction product may be formed on the substrate such that the reaction product adheres to the substrate. The adhered reaction product may be a transition metal oxide layer.

If the transition metal oxide layer is formed using the conventional apparatus 10, then the substrate 10 may need to be heated up to approximately 300° C. or higher to obtain a desired resistance switching characteristic. Using the conventional apparatus 10 may result in higher energy consumption and/or limited capability to use other manufacture processes (e.g., a lift-off process). According to conventional method (as described above), if an oxide material is formed (or deposited), then the oxide material may diffuse to a bottom electrode material. A material easily deformed by heat (e.g., plastic) may not be used to form the substrate 12.

Physical and/or electrical characteristics of the transition metal oxide layer may be adjusted depending on an amount of oxygen within the transition metal oxide layer and a bonding state. The oxygen amount and the bonding state may be adjusted by changing a partial pressure of the oxygen gas supplied to the chamber 11.

According to the conventional method of forming the transition metal oxide layer, a significant amount of O₂ gas may be injected to excite the oxidization reaction, making it difficult to lower an inner pressure of the chamber 11 wherein the inner pressure is approximately 10⁻³ torr.

Changing the partial pressure of the oxygen may be imprecise, increasing a defect rate. Due to a relatively higher amount of the oxygen gas supplied to the chamber 11, the oxygen gas may react directly with the transition metal of the target 15 to form a transition metal oxide layer. The target 15 may be contaminated. Transition metal particles discharged from the target 15 may be blocked (or hindered) by contamination. As such, impurities may be discharged with the transition metal particles. The transition metal oxide material may be directly discharged from the target 15 and adhere to the substrate 12, forming a degraded transition metal oxide layer on the substrate 12.

### SUMMARY

Example embodiments relate to a nonvolatile memory device, a layer deposition apparatus and a method of fabricating a nonvolatile memory device using the same.

The layer deposition apparatus may be used to form a transition metal oxide layer by promoting an oxidization reaction between a transition metal and accelerated oxygen ions on a substrate.

According to example embodiments, the layer deposition apparatus may include a chamber capable of holding a substrate, a particle-discharging target directed toward the substrate wherein the target discharges particles as a primary source material for forming a deposited layer, and a first ion beam gun accelerating a first plurality of ions and irradiating the accelerated ions toward the substrate wherein the accelerated ions may be a secondary source material for forming the deposited layer. The transition metal particles may be a primary source of materials for the transition metal oxide layer. The oxygen ions may be a secondary source of materials for the transition metal oxide layer. The inner area of the chamber may be maintained at room temperature while the deposited layer is formed on the substrate.

The layer deposition apparatus may further include a second ion beam gun accelerating and irradiating a second plurality of ions toward the target to discharge the particles from the target.

The deposited layer may be a transition metal oxide layer. The transition metal oxide layer may be formed of an oxide material selected from the group consisting of nickel (Ni), vanadium (V), zinc (Zn), niobium (Nb), titanium (Ti), tungsten (W), cobalt (Co), hafnium (Hf) and copper (Cu).

According to other example embodiments, a method of fabricating a nonvolatile memory device is provided. The method may include discharging particles from a target toward a substrate, accelerating and irradiating a first plurality of ions toward the substrate, forming a reaction product by reacting the discharged particles and the accelerated and irradiated first plurality of ions, and forming a data storage layer including a deposited layer on the substrate wherein the deposited layer may be formed by depositing the reaction product on the substrate. The reaction product, which may be the transition metal oxide layer, may adhere to the substrate. The deposited layer may be formed at room temperature.

The deposited layer may be a transition metal oxide layer. The transition metal oxide layer may be formed of an oxide material selected from the group consisting of nickel (Ni), vanadium (V), zinc (Zn), niobium (Nb), titanium (Ti), tungsten (W), cobalt (Co), hafnium (Hf) and copper (Cu).

According to yet other example embodiments, there is provided a nonvolatile memory device including a data storage layer having a transition metal oxide layer formed by reacting transition metal particles discharged from a target toward a substrate and oxygen ions accelerated and irradiated toward the substrate wherein the transition metal oxide layer may be formed on the substrate. The transition metal oxide layer may adhere to the substrate.

The transition metal oxide layer may be formed of an oxide material selected from the group consisting of nickel (Ni), vanadium (V), zinc (Zn), niobium (Nb), titanium (Ti), tungsten (W), cobalt (Co), hafnium (Hf) and copper (Cu).

### BRIEF DESCRIPTION OF THE DRAWINGS

Example embodiments will be more clearly understood from the following detailed description taken in conjunction with the accompanying drawings. FIGS. 1-7 represent non-limiting, example embodiments as described herein.

FIG. 1 is a diagram illustrating a cross-sectional view of a conventional layer deposition apparatus;

FIG. 2 is a diagram illustrating a cross-sectional view of a layer deposition apparatus according to example embodiments;

FIGS. 3A through 3E are diagrams illustrating cross-sectional view of a method of fabricating a nonvolatile memory device according to example embodiments;

FIG. 4 is a diagram illustrating a cross-sectional view of a nonvolatile memory device fabricated using the method shown in FIGS. 3A through 3E according to example embodiments;

FIG. 5A is a graph illustrating the current-voltage characteristics of transition metal oxide layers formed using a conventional layer deposition apparatus;

FIG. 5B is a graph illustrating the current-voltage characteristics of transition metal oxide layers formed using a layer deposition apparatus according to example embodiments;

FIG. 6 is a graph illustrating a resistance switching characteristic of a transition metal oxide layer formed using a layer deposition apparatus according to example embodiments; and

FIGS. 7A is an atomic force microscope (AFM) image illustrating transition metal oxide layers formed using a conventional layer deposition apparatus; and

FIG. 7B is an atomic force microscope (AFM) image illustrating transition metal oxide layers formed using a layer deposition apparatus according to example embodiments.

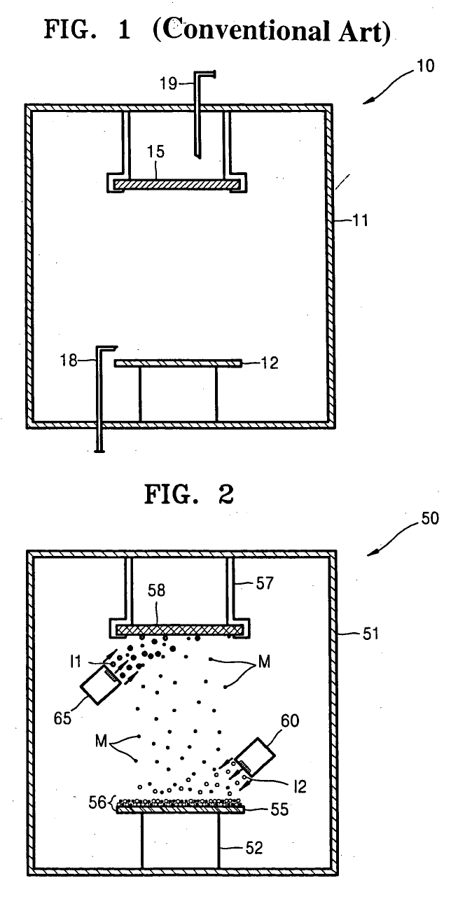

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a nonvolatile memory device, a layer deposition apparatus and a method of fabricating a nonvolatile memory device using the same.

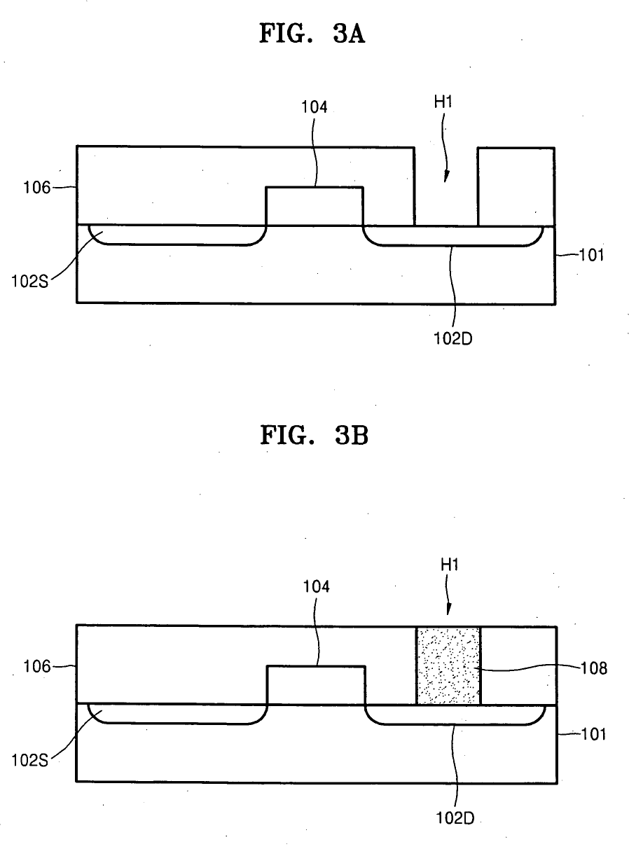

FIG. 2 is a diagram illustrating a cross-sectional view of a layer deposition apparatus according to example embodiments. In FIG. 2, a transition metal oxide layer 56, a transition metal particles (M), argon (Ar) ions (I₁) and oxygen (O₂) ions (I₂) are exaggerated for clarity.

As shown in FIG. 2, a layer deposition apparatus 50 may include a chamber 51, a substrate 55 and a target 58. The inner area of the chamber 51 may be maintained in a partial or complete vacuum state. The substrate 55 may be positioned (or formed) inside the chamber 51. The target 58 may be positioned (or formed) above the substrate 55 inside the chamber 51.

According to example embodiments, the substrate 55 may be supported by a supporter 52 inside the chamber 51. The target 58 may be mounted (or formed) on a holder 57 positioned inside the chamber 51. The target 58 may be a transition metal ingot discharging the transition metal particles, M. The transition metal particles may be a primary source of materials for the transition metal oxide layer 56. The transition metal particles may be a transition metal selected from the group consisting of nickel (Ni), vanadium (V), zinc (Zn), niobium (Nb), titanium (Ti), tungsten (W), cobalt (Co) and hafnium (Hf).

An argon (Ar) ion beam gun 65 and an oxygen (O₂) ion beam gun 60 may be positioned (or formed) inside the chamber 51. The argon (Ar) ion beam gun 65 accelerates and irradiates the Ar ions (I₁) toward the target 58. The O₂ ion beam gun 60 accelerates the O₂ ions (I₂) and irradiates the accelerated O₂ ions toward the substrate 55. The O₂ ions (I₂) may be a secondary source of materials for the transition metal oxide layer 56. The Ar ion beam gun 65 and the O₂ ion beam gun 60 may be any type of particle accelerator. Because various particle accelerators are well-known in the art, a detailed description thereof will be omitted.

If the Ar ions I₁ irradiated by the Ar ion beam gun 65 collide with the surface of the target 58, then the transition metal particles (M) may be discharged from the target 58 and contact (or fall on) the substrate 55. The transition metal particles (M) may react with the O₂ ions (I₂) irradiated by the O₂ ion beam gun 60 and adhere to the substrate 55, forming the transition metal oxide layer 56 on the substrate 55.

The O₂ ion beam gun 60 may accelerate and irradiate the O₂ ions (I₂) in an excited state with energy. Although the substrate 55 may not be heated, an oxidization reaction may occur on the substrate 55 at room temperature, decreasing the likelihood of damage to the substrate 55 due to heat. The oxidization reaction according to example embodiments may have a more simple reaction path than an oxidation reaction induced by heat. The oxidization reaction according to example embodiments may be controlled by a method of adjusting an amount of the irradiated O₂ ions (I₂) and an impinging energy level of the O₂ ions (I₂). As such, characteristics of the transition metal oxide layer 56 may be adjusted by controlling the oxidation reaction.

According to example embodiments, if a small amount of the O₂ ions (I₂) are injected into the chamber, then an inner pressure of the chamber 51 may be lower than the inner pressure observed in the conventional method. As such, an amount of impurities within the transition metal oxide layer 56 may significantly decrease, increasing desirable characteristics of the transition metal oxide layer 56. For example, the average inner pressure of the chamber 51 according to example embodiments is approximately 10⁻⁴ torr.

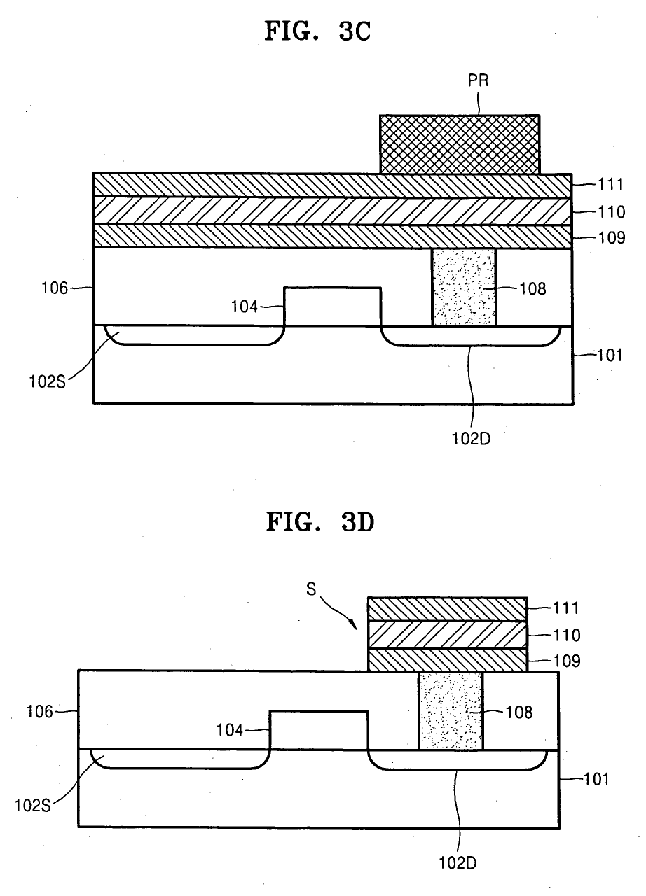

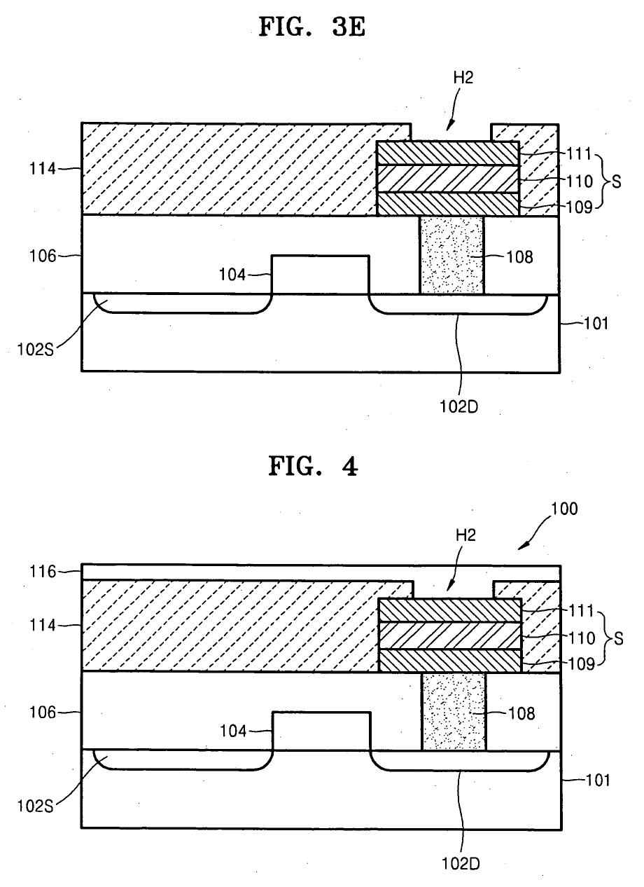

FIGS. 3A through 3E are diagrams illustrating cross-sectional views of a method of fabricating a non-volatile memory device according to example embodiments. FIG. 4 is a diagram illustrating a cross-sectional view of a non-volatile memory device fabricated using the method shown in FIGS. 3A through 3E according to example embodiments.

Referring to FIG. 3A, a transistor may be prepared (or formed) by forming first and second impurity regions 102S and 102D in a substrate 101. A gate structure 104 including a gate electrode may be formed on the substrate 101. Any type of switching device well-known in the art may be used. For example, a diode having a switching function may be used instead of the transistor.

The substrate 101 may be a p-type or n-type semiconductor substrate. The first and second impurity regions 102S and 102D may be formed by doping different types of conductive impurities in the substrate 101 (e.g., n-type or p-type conductive impurities).

A first inter-layer insulation layer 106 may be formed on the substrate 101 to cover the transistor. A contact hole (H₁) exposing the second impurity region 102D may be formed in the first inter-layer insulation layer 106.

Referring to FIG. 3B, a conductive plug 108 may fill the contact hole (H₁). The conductive plug 108 may be formed of aluminium.

Referring to FIG. 3C, a bottom electrode 109 may be formed on the first inter-layer insulation layer 106 to cover the conductive plug 108. The bottom electrode 109 may be formed of a material including platinum (Pt) or titanium nitride (TiN). A data storage layer 110 may be formed on the bottom electrode 109. The data storage layer 110 may be formed of a transition metal oxide material. The data storage layer 110 may be formed of an oxide material selected from the group consisting of nickel (Ni), vanadium (V), zinc (Zn), niobium (Nb), titanium (Ti), tungsten (W), cobalt (Co), hafnium (Hf) and copper (Cu).

The data storage layer 110 may be formed according to a similar method as the transition metal oxide layer 56 shown in FIG. 2, therefore a detailed description thereof will be omitted.

A top electrode 111 may be formed on the data storage layer 110. A photoresist pattern (PR) may be formed thereon. The top electrode 111 may be formed of a material substantially same as the bottom electrode 109. The photoresist pattern (PR) may be formed on (or covering) the conductive plug 108 and a partial region surrounding the conductive plug 108. An exposed portion of the top electrode 111 may be etched using the photoresist pattern (PR) as a mask. A portion of the data storage layer 110 and the bottom electrode 109 may be etched to expose a portion of the first inter-layer insulation layer 106. After the etching, the photoresist pattern (PR) may be removed.

Referring to FIG. 3D, a storage node (S) may be formed from the etching process on the first inter-layer insulation layer 106. The storage node (S) may include the bottom electrode 109, the data storage layer 110 and the top electrode 111. The storage node (S) may be formed on (or covering) the conductive plug 108.

Referring to FIG. 3E, a second inter-layer insulation layer 114 may be formed on the first inter-layer insulation layer 106 and the storage node (S). A portion of the second inter-layer insulation layer 114 may be etched to form an opening (H₂) exposing a portion of an upper surface of the top electrode 111.

Referring to FIG. 4, a plate electrode 116 may be formed on the second inter-layer insulation layer 114, forming a non-volatile memory device 100.

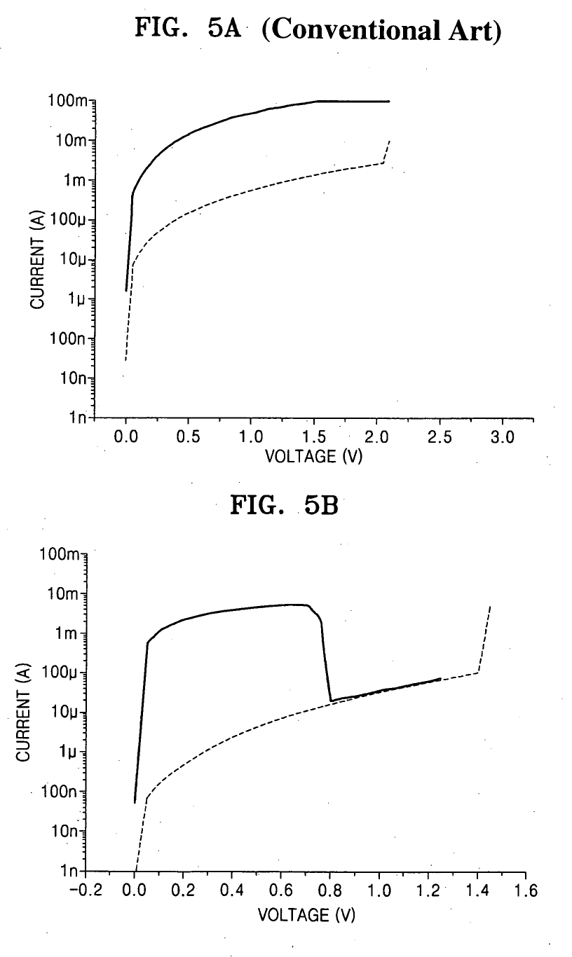

FIG. 5A is a graph illustrating current-voltage characteristics of a transition metal oxide layer formed using a conventional layer deposition apparatus. FIG. 5B is a graph illustrating current-voltage characteristics of a transition metal oxide layer formed using a layer deposition apparatus according to example embodiments.

The results shown in FIGS. 5A and 5B were obtained from a transition metal oxide layer formed of nickel oxide (NiO). In FIG. 5A, the transition metal oxide layer was formed by heating the substrate to approximately 250° C.

In FIGS. 5A and 5B, the dotted line represents an average current output of transition metal oxide layers, which are not programmed, as a result of applying a gradually increasing voltage (hereinafter ‘voltage sweeping’). The solid line represents an average current output of transition metal oxide layers, which are programmed, as a result of voltage sweeping.

Referring to FIG. 5B, the average output current drops when a voltage between approximately 0.7 V and approximately 0.8 V is applied to a programmed transition metal oxide layer formed according to example embodiments.

If a voltage of approximately 0.8V or greater is applied, then the programmed transition metal oxide layers and the non-programmed transition metal oxide layers formed according to example embodiments may exhibit similar current characteristics. As such, the programmed transition metal oxide layer according to example embodiments may have a reset characteristic. The programmed transition metal oxide layer according to example embodiments may be used as a data storage layer of a non-volatile memory device due to the reset characteristic.

Referring to FIG. 5A, the conventional non-programmed transition metal oxide layer did not exhibit the reset characteristic. As such, it may not be desirable to use the conventional non-programmed transition metal oxide layer as a data storage layer of a non-volatile memory device.

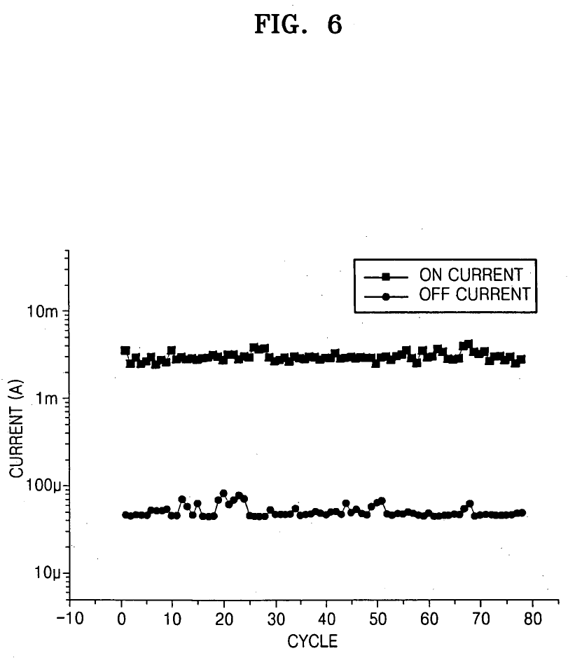

FIG. 6 is a graph illustrating a repetitive switching characteristic of a transition metal oxide layer formed according to example embodiments. The graph illustrated in FIG. 6 correlates with the current-voltage characteristic shown in FIG. 5B.

The programmed transition metal oxide layer formed according to example embodiments was repeatedly subjected to a programming operation and a reset operation using a voltage sweeping. A voltage of approximately 0.5 V was applied between the programming operation and the reset operation. An output current of the programmed transition metal oxide layer was measured.

Referring to FIG. 6, because a large gap exists between the output current level of the transition metal oxide layer in the programmed state and the transition metal oxide layer in the reset state, the output current having the larger current was set to be “on” and the output current level having the smaller current was set to be “off” in order to store binary information.

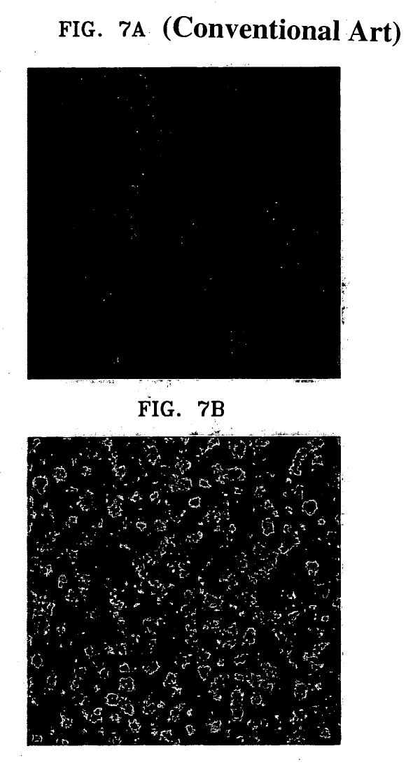

FIG. 7A is an atomic force microscope (AFM) image illustrating transition metal oxide layers formed using a conventional layer deposition apparatus. FIG. 7B is an atomic force microscope (AFM) image illustrating transition metal oxide layers formed using a layer deposition apparatus according to example embodiments.

Referring to FIGS. 7A and 7B, the transition metal oxide layers formed according to example embodiments may have a denser texture and/or smaller grains. The transition metal oxide layers formed according to example embodiments may be smoother. The transition metal oxide layers may have increased adhesion with the substrate and/or increased electrical characteristics.

According to example embodiments, the transition metal oxide layer with increased physical and electrical characteristics may be formed on a substrate. According to example embodiments, increasing the density of the transition metal oxide layer to provide a denser texture may cause the surface of the transition metal oxide layer to be smoother and/or may increase the adhesion between the transition metal oxide layer and the substrate.

Because the transition metal oxide layer may be formed without heating the substrate, the transition metal oxide layer may be formed on the substrate that would normally be deformed by heat (e.g., a plastic substrate).

According to other example embodiments, an oxygen amount in the transition metal oxide layer may be easily adjusted. A level of impurities within the transition metal layer may decrease because the transition metal oxide layer may be formed in a higher vacuum state. According to yet other example embodiments, reliability of non-volatile memory fabrication processes may be increased and/or defects may be reduced.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A layer deposition apparatus, comprising:
a chamber capable of holding a substrate;
a particle-discharging target directed toward the substrate, wherein the target discharges particles as a primary source material for forming a deposited layer; and
a first ion beam gun accelerating a first plurality of ions and irradiating the accelerated ions toward the substrate, wherein the accelerated ions are a secondary source material for forming the deposited layer.

2. The apparatus of claim 1, wherein the particles are transition metal particles, the accelerated ions are oxygen ions, the first ion beam gun is an oxygen ion beam gun and the deposited layer is a transition oxide metal layer.

3. The apparatus of claim 1, further comprising a second ion beam gun directed at the particle-discharging target, where the second ion bean gun accelerates and irradiates a second plurality of ions toward the particle-discharging target.

4. The apparatus of claim 3, wherein the second ion beam gun is an argon beam gun, and the second plurality of ions are argon ions.

5. The apparatus of claim 1, wherein an inner area of the chamber is maintained at room temperature.

6. The apparatus of claim 1, wherein an inner pressure of the chamber is maintained 10⁻⁴ torr or lower.

7. The apparatus of claim 1, wherein the substrate is formed of a material deformable by heat.

8. The apparatus of claim 7, wherein the material is plastic.

9. A method of fabricating a nonvolatile memory device, comprising:
discharging particles from a target toward a substrate;
accelerating and irradiating a first plurality of ions toward the substrate;
forming a reaction product by reacting the discharged particles and the accelerated and irradiated first plurality of ions; and
forming a data storage layer including a deposited layer on the substrate, wherein the deposited layer is formed by depositing the reaction product on the substrate.

10. The method of claim 9, wherein the particles are transition metal particles, the first plurality of ions are oxygen ions, the reaction product is a transition metal oxide and the deposited layer is a transition oxide metal layer.

11. The method of claim 9, wherein discharging the particles includes accelerating and irradiating a second plurality of ions toward the target.

12. The method of claim 11, wherein the second plurality of ions are argon ions.

13. The method of claim 9, wherein the deposited layer is formed at room temperature.

14. The method of claim 9, wherein accelerating and irradiating the first plurality of ions includes controlling an amount of the irradiated first plurality of ions.

15. A nonvolatile memory device, comprising:
a data storage layer having a transition metal oxide layer formed by reacting transition metal particles discharged from a target toward a substrate and oxygen ions accelerated and irradiated toward the substrate, wherein the transition metal oxide layer is formed on the substrate.

16. The nonvolatile memory device of claim 15, wherein the transition metal oxide layer is formed of an oxide material selected from the group consisting of nickel (Ni), vanadium (V), zinc (Zn), niobium (Nb), titanium (Ti), tungsten (W), cobalt (Co), hafnium (Hf) and copper (Cu).

17. The nonvolatile memory device of claim 15, wherein the transition metal oxide layer is formed at room temperature.

18. The nonvolatile memory device of claim 15, wherein the substrate is formed of a material deformable by heat.

19. The nonvolatile memory device of claim 18, wherein the material is plastic.

20. The nonvolatile memory device of claim 15, wherein transition metal oxide layer exhibits a reset characteristic.
